(19) United States
(12) Patent Application Publication
(10) Pub. No.: US 2006/0249305 A1
(43) Pub. Date: Nov. 9, 2006

(54) Use of a component as an integral part of an overall EMI shield for a computing device

(75) Inventors: J. David Egner, Sammamish, WA (US); Jeffrey Mark Reents, Carnation, WA (US); Roy James Askeland, Los Altos, CA (US)

Correspondence Address: WOODCOCK WASHBURN LLP (MICROSOFT CORPORATION), ONE LIBERTY PLACE - 46TH FLOOR, PHILADELPHIA, PA, 19103, US

(73) Assignee: Microsoft Corporation, Redmond, WA (US)

(21) Appl. No.: 11/123,683

(22) Filed: May 6, 2005

(51) Int. Cl. H05K 9/00

(52) U.S. Cl. 174/382; 174/377

(57) ABSTRACT

A method and system are provided for shielding electromagnetic interference (EMI). A first component and a second component are provided, whereby the two components are integrated in such a way that the second component, although only partially shielding itself, extends the EMI shielding ability of the first component. The second component can be an optical device drive (ODD) that provides only partial shielding when its tray is opened to insert an optical disk. However, because the ODD is integrated with the first component, which can be a gaming console, in such a way that no internal EMI generated by hardware internal to the first component can escape, the second component is used as an integral EMI shield of the first component.

### COPYRIGHT NOTICE AND PERMISSION

A portion of the disclosure of this patent document may contain material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice shall apply to this document: Copyright © 2005, Microsoft Corp.

### FIELD OF THE INVENTION

The present invention generally relates to the field of EMI shielding. More specifically, the present invention relates to systems and methods for using an assembly as an integral component of on overall EMI shield for a computing device.

### BACKGROUND OF THE INVENTION

Computing devices have components that produce electromagnetic interference (EMI). In order for these computing devices to be marketable and shippable to consumers, any EMI internal to the devices must be contained so that they do not cause interference with surrounding electronics. Typical computing device components, such as processor circuits (CPUs), memory systems, digital video and audio systems, digital networking interfaces, hard drives or optical drives, may produce a spectrum of EMI, ranging anywhere from a few kilohertz (10³ Hz) to a few gigahertz (10⁹ Hz). This EMI may have undesirable effects on all kinds of electrical circuits surrounding the computing devices, including TVs, PCs, and radios.

One way to contain such internal EMI is to use a Faraday cage as an enclosure of the computing device, thereby shielding any EMI produced by the computing device components located inside the enclosure. A Faraday cage is simply an earthed metal screen surrounding a piece of equipment to protect it from external electromagnetic interference signals, or conversely, to protect the external environment from interference signals originating internally to the equipment.

A problem arises when the computing devices must be accessed externally. For example, if a computing device, such as a gaming console, contains an embedded device such as an optical disk drive, this drive's tray must be opened in order to insert an optical disk (such as CD-ROM, DVD-ROM, etc.). When the tray of the optical device is opened, EMI internal to the computing device will escape via the optical disk drive that is embedded in the computing device. A typical opening of a tray is about five to six inches in diagonal length. This five to six inch opening is a kind of aperture antenna that radiates EMI from inside the console to the outside surrounding environment. Any frequency that is one-fourth of the wavelength (or higher) of the five to six inch aperture can radiate out through the tray. This radiation of EMI can cause interference with electronics in the surrounding environment.

Thus, it would be desirable to implement an EMI shield such that no internal EMI to computing devices would escape to the surrounding environment while at the same time allowing embedded devices, such as optical drives, to be opened so that optical disks or equivalent components can be inserted into the embedded devices. Specifically, it would be desirable to extend the EMI shield of the computing device by using the EMI shield of the embedded device by integrating these two devices.

Moreover, it would be desirable to use the embedded device's EMI shield in such a way as to obviate the need to provide additional EMI shields. Specifically, it would be desirable to eliminate pre-fabricated EMI shields or Faraday cages that may exist in the computing devices—cages that serve as drive bays for the embedded device. Instead, it would be desirable to use the EMI shield of the embedded device itself as extending the EMI shield of the computing device, thereby saving metals that may be needed to build a total functioning EMI shield. In short, it would be desirable to use less metal to build EMI shields by leveraging the EMI shield of an embedded device.

By using less metal to build EMI shields, it would be possible and desirable to reduce the physical size of the computing device. Physical dimensions of computing devices, such as gaming consoles, are often very important in making such consoles marketable and economically competitive. By using the EMI shield of an embedded device and not needing to provide a separate EMI shield would reduce the size of the overall computing device.

Thus, for at least these three reasons discussed above, namely, (1) preventing internal EMI to the computing device from escaping via a tray opening of an embedded device, (2) leveraging the EMI shield of the embedded device to obviate the need for additional metals for EMI shielding, and (3) reducing the overall size of the computing device as a result of using less metal, the present invention fulfills important needs in the state of the art heretofore not addressed.

### SUMMARY OF THE INVENTION

A method and system are provided whereby one component's EMI shield can be extended by insertion of a second component that does not have complete EMI shielding. In one aspect of the invention, an enclosure, such as a gaming console, that has a complete EMI shield can house a second component, such as an optical device drive (ODD), which only has a partial EMI shield. When the ODD tray is opened to insert an optical disk, such as a CD-ROM or DVD, internal EMI of the enclosure cannot escape to the external environment via the ODD tray opening. The reason such EMI cannot escape is that the outside walls of the ODD that provide EMI shielding are integrated with the EMI shielded walls of the enclosure.

In another aspect of the invention, the enclosure and the ODD are integrated via spring fingers such that both the enclosure and the ODD has a substantially similar electrical surface potential. This type of integration provides an overall enclosure-cum-ODD Faraday cage that prevents any internal EMI emanating from the enclosure from escaping to the outside environment of the enclosure. In yet another aspect of the invention, no apertures greater than 5 mm in the greatest aperture dimension exist between the integrated enclosure and ODD.

Additional features of the invention will be made apparent from the following detailed description of illustrative aspects that proceed with reference to the accompanying drawings.

### BRIEF DESCRIPTION OF THE DRAWINGS

The foregoing summary, as well as the following detailed description of the invention, is better understood when read in conjunction with the appended drawings. In order to illustrate the invention, various aspects of the invention are shown. However, the invention is not limited to the specific systems and methods disclosed. The following figures are included:

FIG. 1 provides a general illustration of a first component with electromagnetic interference (EMI) shielding and a second component with partial EMI shielding being integrated;

FIG. 2 illustrates an optical disk drive (ODD) installed as part of an overall system enclosure that shields EMI;

FIG. 3A illustrates integration of the walls of an ODD as part of an overall system enclosure that shields EMI;

FIG. 3B illustrates exemplary integration aspects of the ODD and the enclosure using contact fingers attached to the enclosure and capable of making contact with the ODD;

FIG. 4 illustrates the extension of the enclosure EMI shield by integration with an ODD;

FIG. 5 illustrates an exemplary implementation of the enclosure and the ODD components; and

FIG. 6 is a block diagram showing an exemplary multimedia console, in which many computerized processes emitting EMI may require shielding.

### DETAILED DESCRIPTION OF ILLUSTRATIVE EMBODIMENTS

Overview

Use of a component, such as an optical device drive (ODD), is provided, where the ODD acts as an integral part of an overall EMI enclosure which shields internal EMI of a computing device, such as a gaming console. The ODD extends the EMI shield of the enclosure while at the same time allowing external access to the enclosure. Thus, when a CD-ROM or DVD are inserted into the ODD and the ODD tray is opened, potentially providing an opening for the aforementioned internal EMI to escape, the ODD shielding is actually integrated in such a way as to prevent these EMI from escaping.

Moreover, a typical gaming console is provided that is responsible for generating internal EMI. This gaming console provides a listing of typical devices that might generate EMI that have to be prevented from escaping to the outside environment.

Aspects of a Component as an Integral Part of an Overall EMI Shield

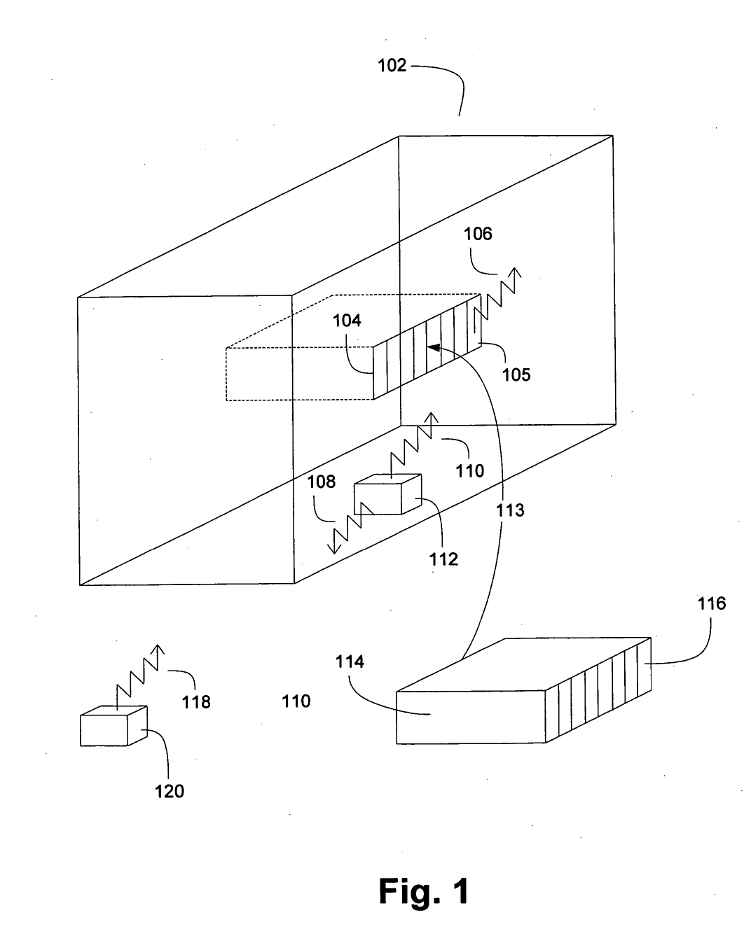

In one aspect of the invention, FIG. 1 presents a general illustration of a first component with EMI shielding and a second component with partial shielding being integrated. A first component 102 is illustrated, where the first component 102 is a Faraday cage that provides a shield against EMI. Specifically, the first component 102 provides a shield against EMI 108 and 110 being generated by some internal device 112. The first component 102 keeps the EMI inside itself and does not allow them to escape outside. However, equivalently, the first component 102 also provides a shielding against externally originating EMI 118 (emanating from some external device 120) from penetrating the first component 102, so that such external EMI 118 does not interfere with any internal devices 112 of the first component 102.

However, the first component 102 also may have an aperture 104 that does not shield 105 (illustrated by the vertical lines, in contrast to the solid filling of the rest of the first component 102) and allows some EMI 106 to escape outside the first component 102. This aperture 104 may be plugged by another component, a second component 114. This component 114 can only have partial EMI shielding. In other words, it can be thought of as a six sided box with at least one metal face missing, so that it does not shield EMI from escaping with regard to at least one face. The missing metal face is illustrated by the vertical lines 116.

This second component 114 can plug into 113 the first component 102 such that no EMI 106, 108, or 110 will escape. The second component 114 does not have to be completely shielding to plug EMI from escaping from the first component 102. It can be merely partially EMI shielding. As long as the surface of the second component 114 electrically connects with the surface of the first component 102, an EMI shield is created for first component 102. In effect, the second component 114 extends the EMI shield of the first component 102 while being itself only partially shielding. The fact that the second component 114 does not have to be completely shielded in order to plug the aperture 104, means that objects, such as an optical disk drives (ODDs), with external EMI shielding, can be used as the second component. When an ODD is opened, no EMI 106, 108, 110 can escape via the open face 116 of the plugged in second component 114 since the EMI shield of the first component 102 is extended by the second component's 114 external EMI shield.

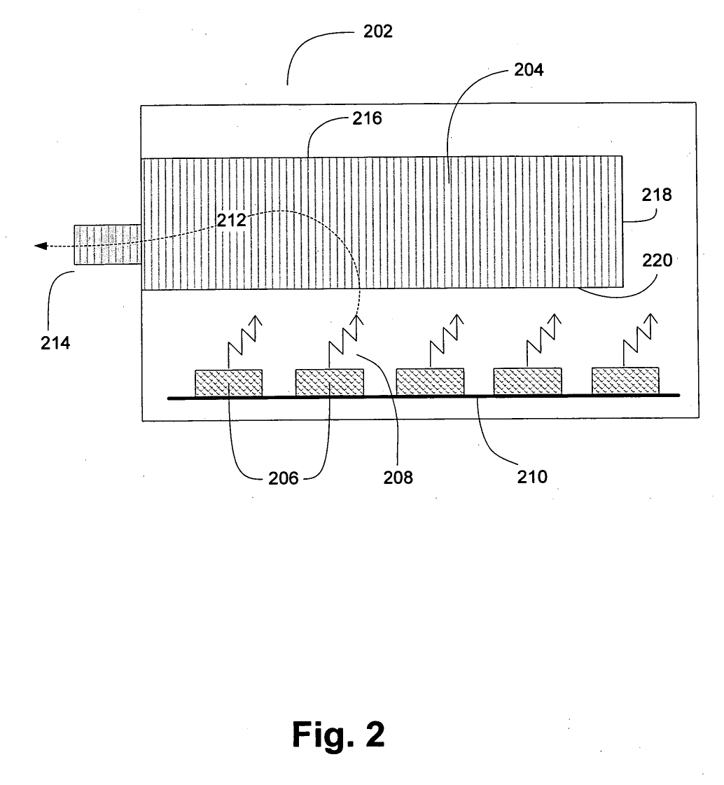

In another aspect of the invention, an ODD is illustrated as being installed in an overall system enclosure. In FIG. 2, an overall computer system enclosure 202 encloses computer system hardware 206 and any other circuitry. Such hardware 206, located, for example, on a motherboard 210, produces internal EMI 208. One of the goals of the ODD 204 is to provide shielding in unison with the enclosure 202, such that the internal EMI 208 does not escape 212 to the outside of the enclosure 202 via an aperture or ODD tray 214. If the ODD 204 did not provide shielding along walls 216, 218, and 220, internal EMI could easily escape to the outside of the enclosure 202 via the aperture 214 (being otherwise incapable to escape via another other passages, since the rest of the enclosure 202 is EMI shielded).

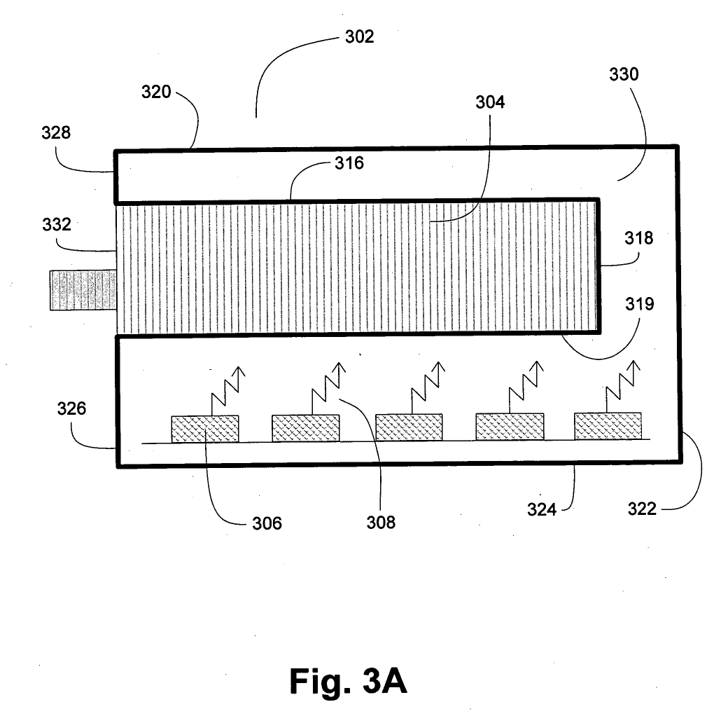

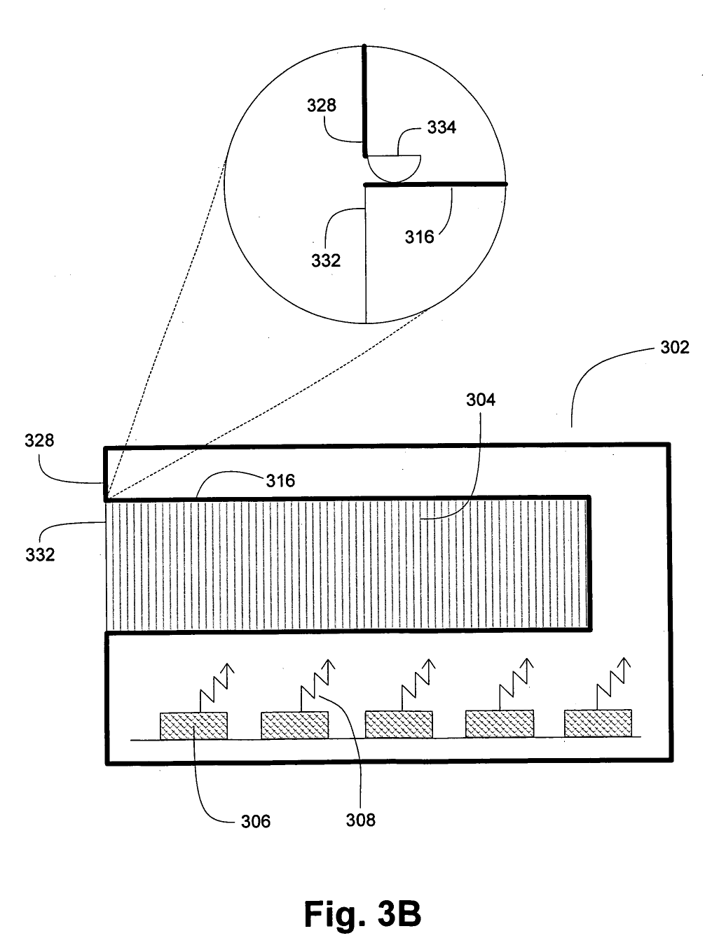

To further illustrate the integration of the ODD and the enclosure, FIG. 3A emphasizes relationship of the walls of the ODD and the enclosure illustrated in FIG. 2. Thus, the overall system enclosure 302 houses an ODD 304 and it consists of five walls: 320, 322, 324, 326, and 328. The ODD 304 becomes integrated with the enclosure 302 because the ODD's 304 walls connect to the walls of the enclosure 302. This integration is show in FIG. 3A is solid bold lines.

Specifically, ODD wall 316 connects to enclosure wall 328, and ODD wall 319 connects to enclosure wall 326. Thus, the combination of walls 328-320-322-324-326-319-318-316 forms a faraday cage from which EMI 308, generated by internal hardware 306, cannot escape—and hence it is limited to the internal space 330 of the enclosure 302.

The point of integration of the ODD and the enclosure is further illustrated in FIG. 3B. FIG. 3B blows up in size a portion of FIG. 3A by focusing on the point of contact of wall 328 with wall 316. The contact between the two walls is made by a spring finger 334 that is attached to wall 328 and upon insertion of the ODD 304 into the enclosure 302, the spring finger 334 makes contact with the ODD 304. This contact ensures that the surface potential of the enclosure 302 and the ODD 304 are substantially similar. The ODD 304, as depicted in FIG. 3B is inserted through opening 332. A similar contacting mechanism applies to walls 319 and 326 depicted in FIG. 3A.

Although only one finger 334 is depicted in FIG. 3B, there are numerous fingers that make contact between the enclosure 302 and the ODD 304. The spring fingers are placed at regular intervals along the perimeter interface (point of integration) between the drive enclosure and the overall enclosure. This ensures that the surface potential remains essentially the same, everywhere along the interface. The spacing of those fingers can be important since it will determine the wavelength of EMI 308 getting through from the inside hardware 308 to the outside. Generally speaking, the closer the spacing between the fingers, the more frequencies are kept from getting out of the enclosure 304. In one design aspect of the invention, no apertures exist between the ODD 304 and the enclosure 302 that are greater than 5 millimeters in length of greatest dimension of the aperture. In another aspect of the invention, any aperture in the ODD shielding is of a size equal to or smaller than any aperture of the enclosure, thereby ensuring that EMI internal to the enclosure don't escape via the ODD shielding.

One of the numerous benefits of using the outer skin of the ODD 304 as an internal shielding device for the enclosure 302 is that such a solution saves metal. Instead of having a guard rail or something equivalent thereto that may provide a Faraday cage that is integrated with the enclosure 302, the outside of the ODD 304 itself is used to complete a Faraday cage along with the enclosure. Thus, the need for such a guard rail is obviated and less metal can be used. The use of less metal means that the cost of an overall product using the enclosure 302 and ODD 304 is reduced, and moreover, the physical size of the product is reduced. All these benefits are concurrent with the ability of the enclosure 302 and ODD 304 combination to contain any internal EMI 308.

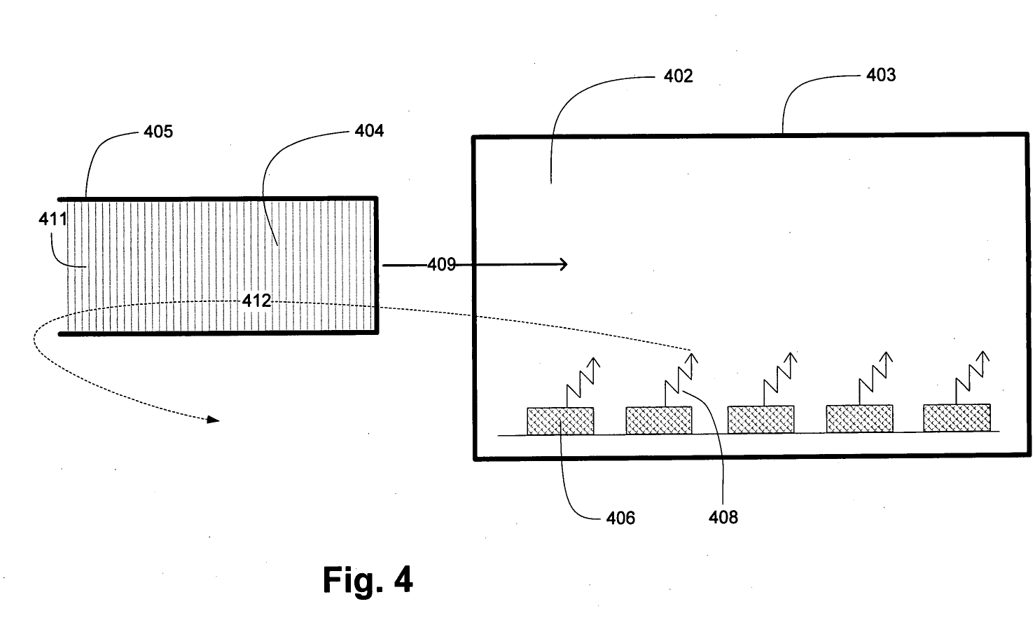

In another aspect of the invention, FIG. 4 illustrates the extension of the enclosure 402 EMI shield 403 by integrating the ODD 404 EMI shield 405 with the enclosure 402 EMI shield 403. Before the ODD 404 is inserted 409 into the enclosure 402, EMI 408 are confined to the enclosure 402. After insertion, if the ODD did not have proper EMI shielding 405, this EMI 408 could escape 412 via the opening 411. The reason the EMI can escape is because the typical ODD 404 does not itself provide any EMI shielding. However, the ODD 404 depicted in FIG. 4, does provide an EMI shield 405. The result of the ODD 404 providing such a shield 405 is that it extends the EMI shield 403 of the enclosure 402. The extension of the enclosure 402 EMI shield 403 depends on adequate integration between the enclosure 402 and the ODD 404, as discussed with reference to FIG. 3A and especially FIG. 3B, which uses spring fingers to integrate the enclosure 402 and the ODD 404.

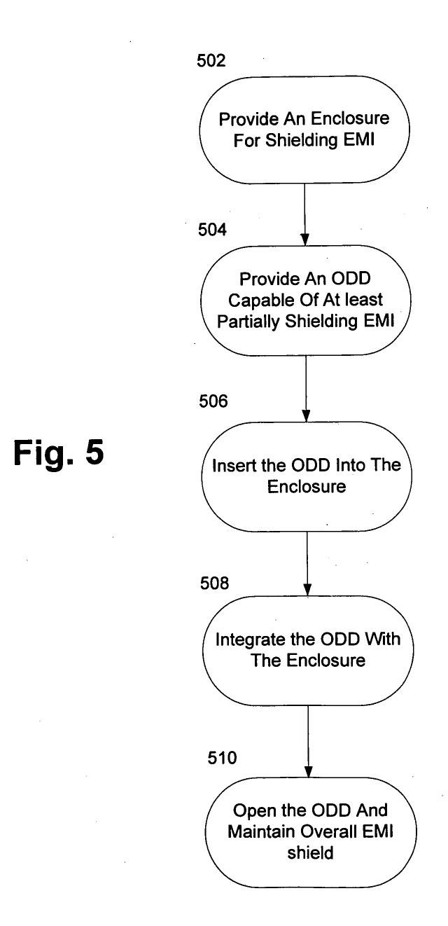

FIG. 5 depicts in a flowchart an exemplary implementation of an enclosure and an ODD, both of which are integrated to provide EMI shielding of internal enclosure EMI emitting devices. At block 502, an enclosure is provided. This enclosure can be, for example, a gaming console. This enclosure is capable of shielding internal EMI to the enclosure. In other words, the enclosure is a Faraday cage that traps internally emitted EMI from escaping to the outside environment so that the EMI cannot create electromagnetic interference with other external electronic devices. The enclosure must be such that EMI frequencies of a desired wavelength do not escape. Thus, for example, in one aspect of the invention the enclosure does not have any apertures that are greater than 5 millimeters is diameter or length from the two farthest points apart in any given aperture.

At block 504, a second component or enclosure is provided, specifically, an ODD, that at least provides partial shielding of EMI. It is that partial shielding that can eventually be integrated with the EMI shielding of the enclosure to provide a sealed off Faraday cage preventing any EMI internal to the enclosure from escaping outside the enclosure. Typically, the front-panel tray opening of an ODD is not shielded at all, and EMI can pass through it, unimpeded. Moreover, the typical ODD enclosure is not directly designed with the spectrum of an overall system's EMI in mind. The ODD enclosure is designed with consideration for suppressing its local, self-generated EMI only. This shielding, if present at all, can only be considered as partial shielding from the overall system's perspective. Thus, when such partially shielded EMI are inserted into shielded enclosures, they provide an opening for internal EMI of the computing system's enclosure to escape to outside the enclosure.

Even in the scenario where the ODD may be such that it provides shielding at its opening so that when the opening is closed it does provide an integrated shield with the enclosure in which it is inserted, when the ODD is opened EMI can escape. For example, any time an optical disk is inserted into the ODD, the ODD tray must be opened and during this time and through the tray opening EMI internal to the enclosure can escape and cause electromagnetic interference with any electronics outside the enclosure.

To prevent this from happening, the partially shielding ODD must be integrated in such a way that it does not make a difference whether the ODD tray is opened or not. One way to accomplish this goal is to provide EMI shielding to the outside of the ODD and use this shielding as an integrated part of the enclosure shielding. In other words, the goal is to extend the enclosure shielding by integrating this enclosure shielding with the ODD shielding. One advantage of such an integration is that the entire ODD does not have to be shielded, instead, only that part which will at once prevent internal EMI to the enclosure from escaping and at the same time allow any optical disk to be inserted without exposing the outside of the enclosure to the internal EMI.

At block 506, the ODD is inserted into the enclosure. The insertion should be such that there is substantial integration between the ODD and the enclosure. The ODD can be embedded into the enclosure, such that a tray of the ODD can be opened in order to externally insert an optical disk (e.g. a CD-ROM or DVD) into the ODD.

At block 508, the ODD is integrated with the enclosure. Integration is accomplished in the form of an electrical connection of the ODD and the enclosure. This connection, moreover, is accomplished by spring fingers that are attached to the enclosure and upon insertion of the ODD, these fingers make electrical contact with the ODD.

Finally, at block 510, the ODD tray can be opened in order to insert an optical disk. However, even upon opening of the ODD, any EMI internal to the enclosure do not escape to the surrounding environment via the ODD and the tray. The external shielding of the ODD is integrated with the enclosure to form one overall EMI shield, i.e., a Faraday cage. Notably, this cage not only prevents internal EMI signals from escaping but it also prevents any external signals from penetrating the cage, preventing interference with the internal components of the enclosure.

Exemplary Multimedia Console Capable of Producing EMI

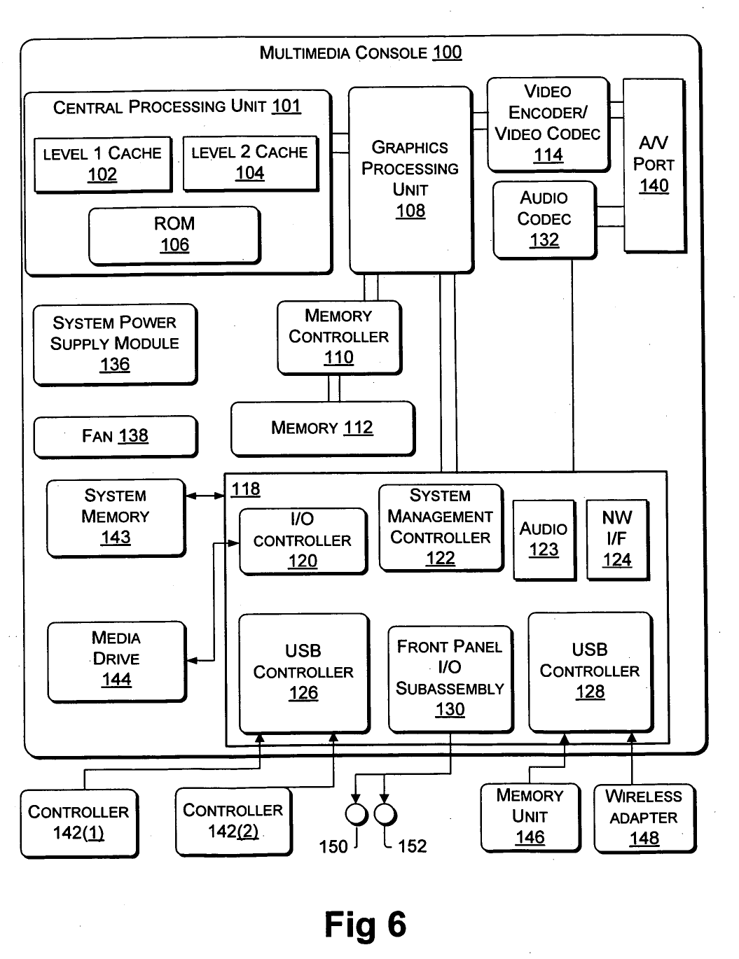

Referring next to FIG. 6, a block diagram shows an exemplary multimedia console that may be implemented inside the enclosure discussed above. Some of the components of the media console will produce EMI that will have to be contained by the enclosure. Every component that operates on electromagnetic principles will generate some quantity of EMI internal to the enclosure.

For example, digital audio processing may be implemented in the multimedia console 100 of FIG. 6. The multimedia console 100 has a central processing unit (CPU) 101 having a level 1 (L1) cache 102, a level 2 (L2) cache 104, and a flash ROM (Read-only Memory) 106. The level 1 cache 102 and level 2 cache 104 temporarily store data and hence reduce the number of memory access cycles, thereby improving processing speed and throughput. The flash ROM 106 may store executable code that is loaded during an initial phase of a boot process when the multimedia console 100 is powered. Alternatively, the executable code that is loaded during the initial boot phase may be stored in a FLASH memory device (not shown). Further, ROM 106 may be located separate from CPU 101.

A graphics processing unit (GPU) 108 and a video encoder/video codec (coder/decoder) 114 form a video processing pipeline for high speed and high resolution graphics processing. Data is carried from the graphics processing unit 108 to the video encoder/video codec 114 via a bus. The video processing pipeline outputs data to an A/V (audio/video) port 140 for transmission to a television or other display. A memory controller 110 is connected to the GPU 108 and CPU 101 to facilitate processor access to various types of memory 112, such as, but not limited to, a RAM (Random Access Memory).

The multimedia console 100 includes an I/O controller 120, a system management controller 122, an audio processing unit 123, a network interface controller 124, a first USB host controller 126, a second USB controller 128 and a front panel I/O subassembly 130 that are preferably implemented on a module 118. The USB controllers 126 and 128 serve as hosts for peripheral controllers 142(1)-142(2), a wireless adapter 148, and an external memory unit 146 (e.g., flash memory, external CD/DVD ROM drive, removable media, etc.). The network interface 124 and/or wireless adapter 148 provide access to a network (e.g., the Internet, home network, etc.) and may be any of a wide variety of various wired-or wireless interface components including an Ethernet card, a modem, a Bluetooth module, a cable modem, and the like.

System memory 143 is provided to store application data that is loaded during the boot process. A media drive 144 is provided and may comprise a DVD/CD drive, hard drive, or other removable media drive, etc. The media drive 144 may be internal or external to the multimedia console 100. Application data may be accessed via the media drive 144 for execution, playback, etc. by the multimedia console 100. The media drive 144 is connected to the I/O controller 120 via a bus, such as a Serial ATA bus or other high speed connection (e.g., IEEE 1394).

The system management controller 122 provides a variety of service functions related to assuring availability of the multimedia console 100. The audio processing unit 123 and an audio codec 132 form a corresponding audio processing pipeline with high fidelity, 3D, surround, and stereo audio processing according to aspects of the present invention described above. Audio data is carried between the audio processing unit 123 and the audio codec 126 via a communication link. The audio processing pipeline outputs data to the A/V port 140 for reproduction by an external audio player or device having audio capabilities.

The front panel I/O subassembly 130 supports the functionality of the power button 150 and the eject button 152, as well as any LEDs (light emitting diodes) or other indicators exposed on the outer surface of the multimedia console 100. A system power supply module 136 provides power to the components of the multimedia console 100. A fan 138 cools the circuitry within the multimedia console 100.

The CPU 101, GPU 108, memory controller 110, and various other components within the multimedia console 100 are interconnected via one or more buses, including serial and parallel buses, a memory bus, a peripheral bus, and a processor or local bus using any of a variety of bus architectures.

When the multimedia console 100 is powered on or rebooted, application data may be loaded from the system memory 143 into memory 112 and/or caches 102, 104 and executed on the CPU 101. The application may present a graphical user interface that provides a consistent user experience when navigating to different media types available on the multimedia console 100. In operation, applications and/or other media contained within the media drive 144 may be launched or played from the media drive 144 to provide additional functionalities to the multimedia console 100.

The multimedia console 100 may be operated as a standalone system by simply connecting the system to a television or other display. In this standalone mode, the multimedia console 100 may allow one or more users to interact with the system, watch movies, listen to music, and the like. However, with the integration of broadband connectivity made available through the network interface 124 or the wireless adapter 148, the multimedia console 100 may further be operated as a participant in a larger network community.

All of the above discussed console components will produce EMI; the net result is a family of related harmonics ranging in spectral frequency. The enclosure provides an EMI shield that prevents any relevant signals that may interfere with the outside environment from escaping through apertures of designated maximum dimensions.

While the present invention has been described in connection with the preferred aspects, as illustrated in the various figures, it is understood that other similar aspects may be used or modifications and additions may be made to the described aspects for performing the same function of the present invention without deviating therefrom. For example, in one aspect of the invention, a component was described, whereby the component can integrate with another component and thus extend the EMI shield of that other component. However, other equivalent systems and methods to these described aspects are also contemplated by the teachings herein. Therefore, the present invention should not be limited to any single aspect, but rather construed in breadth and scope in accordance with the appended claims.

1. A system for shielding electromagnetic interference, comprising:
a first component with an electromagnetic shield; and
a second component with a partial electromagnetic shield, wherein the second component by itself extends the electromagnetic shield of the first component by integrating with the first component.

2. The system according to claim 1, wherein the first component is separate from the second component before integration.

3. The system according to claim 1, wherein the first component shields electromagnetic interference that is internal to the first component signals.

4. The system according to claim 1, wherein the second component shields electromagnetic interference that is internal to the first component signals.

5. The system according to claim 1, wherein the first component and the second component are integrated to maintain a substantially similar surface conductivity between the first component and the second component.

6. The system according to claim 1, wherein the first component and the second component are integrated via an electrical connection.

7. The system according to claim 1, wherein the second component has a partial electromagnetic shield as a result of an aperture created by opening a tray of the second component.

8. A method for shielding electromagnetic interference, comprising:
providing a first component with an electromagnetic shield; and
providing a second component with a partial electromagnetic shield, wherein the second component by itself extends the electromagnetic shield of the first component by integrating with the first component.

9. The method according to claim 8, wherein the first component is separate from the second component before integration.

10. The method according to claim 8, wherein the first component shields electromagnetic interference that is internal to the first component signals.

11. The method according to claim 8, wherein the second component shields electromagnetic interference that is internal to the first component signals.

12. The method according to claim 8, wherein the first component and the second component are integrated to maintain a substantially similar surface conductivity between the first component and the second component.

13. The method according to claim 8, wherein the first component and the second component are integrated via an electrical connection.

14. The method according to claim 8, wherein the second component has a partial electromagnetic shield as a result of an aperture created by opening a tray of the second component.

15. A method for shielding electromagnetic interference, comprising:
using a first component with an electromagnetic shield; and
using a second component with a partial electromagnetic shield, wherein the second component by itself extends the electromagnetic shield of the first component by integrating with the first component.

16. The method according to claim 15, wherein the first component is separate from the second component before integration.

17. The method according to claim 15, wherein the first component shields electromagnetic interference that is internal to the first component signals.

18. The method according to claim 15, wherein the second component shields electromagnetic interference that is internal to the first component signals.

19. The method according to claim 15, wherein the first component and the second component are integrated to maintain a substantially similar surface conductivity between the first component and the second component.

20. The method according to claim 15, wherein the first component and the second component are integrated via an electrical connection.
